(19) United States
(12) Patent Application Publication
(10) Pub. No.: US 2011/0232745 A1
(43) Pub. Date: Sep. 29, 2011

(54) ANTIREFLECTION COATING FOR MULTI-JUNCTION SOLAR CELLS

(75) Inventors: Lucas Alves, Occidental, CA (US); Paul Morand, Rohnert Park, CA (US)

(73) Assignee: Deposition Sciences, Inc., Santa Rosa, CA (US)

(21) Appl. No.: 13/070,091

(22) Filed: Mar. 23, 2011

Related U.S. Application Data
(60) Provisional application No. 61/316,772, filed on Mar. 23, 2010.

(51) Int. Cl. H01L 31/0216; G02B 1/11; H01L 31/0232; C23C 14/34; C01B 33/12

(52) U.S. Cl. 136/256; 359/601; 359/586; 204/192.26; 423/335

(57) ABSTRACT

A photovoltaic solar cell having a multi-layer antireflective coating on an outer surface. The coating may include alternating layers of silicon dioxide and tantalum pentoxide and may have average front surface reflectance of less than five percent over the wavelength range from 300 nm to 1850 nm with the silicon dioxide having a refractive index less than 1.4 at a wavelength of 550 nm.

### RELATED APPLICATIONS

The instant application is co-pending with and claims the priority benefit of U.S. Provisional Patent Application No. 61/316,772 filed Mar. 23, 2010, entitled “Efficiency Enhancement Antireflection Coating on Multi-junction Solar Cells,” the entirety of which is incorporated herein by reference.

### BACKGROUND

Embodiments of the present subject matter generally relate to antireflective layers and coatings for various applications, such as, but not limited to, multi-junction solar cells, solar arrays, and the like.

Considerable research and development have been conducted recently in solar cell semiconductor materials and solar cell structural technologies. As a result, advanced semiconductor solar cells have been applied to a number of commercial and consumer-oriented applications. For example, solar technology has been applied to satellites, space, mobile communications, and so forth. Energy conversion from solar energy or photons to electrical energy is an important issue in the generation of solar energy. For example, in satellite and/or other space related applications, the size, mass, and cost of a satellite power system are directly related to the power and energy conversion efficiency of the solar cells used. The efficiency of energy conversion, which converts solar energy (or photons) to electrical energy, depends upon various factors such as solar cell structures, semiconductor materials, etc. Thus, energy conversion for each solar cell is generally dependent upon the effective utilization of the available sunlight across the solar spectrum. As such, the characteristic of sunlight absorption in semiconductor material is important to determine the efficiency of energy conversion.

Conventional solar cells typically use compound materials such as indium gallium phosphide (InGaP), gallium arsenic (GaAs), germanium (Ge) and so forth, to increase coverage of the absorption spectrum from UV to 890 nm. For example, the addition of a Ge junction to a cell structure may extend the absorption range (i.e., to approximately 1800 nm). Thus, selection of semiconductor compound materials may enhance the performance of the solar cell.

Physical or structural design of solar cells may also enhance the performance and conversion efficiency of solar cells. Solar cells have been typically designed in multi-junction structures to increase the coverage of the solar spectrum. Solar cells are normally fabricated by forming a homo-junction between an n-type layer and a p-type layer with the thin, topmost layer of the junction on the side of the device having incident radiation thereon as the emitter and the relatively thick bottom layer as the base.

Further, concentrated solar energy collection systems, e.g., concentrated photovoltaic (CPV) solar cells, typically require reflecting large parts of the electromagnetic spectrum. For example, the electromagnetic spectrum at ground level contains significant energy in the range from 300 nm to about 2500 nm, and advances in materials research and semiconductor epitaxy have enabled higher conversion efficiencies in CPV solar cells in this spectrum. Further, the contribution from band-gap modulation, multi junction cell morphology and illuminant/concentrator standardization have allowed for an approximately two hundred percent increase in external quantum efficiencies in the last decade. Due to the available types of semiconductor materials, there is a particular need for high efficiency in the short wavelength region of this range, from about 300 nm to about 450 nm. If insufficient light is available in this wavelength range, however, the semiconductor junction responsible for converting this light may become reverse biased and limit the power output of other junctions depending upon the structure of the cell. Thus, a mechanism is needed in the art to enhance the performance of multi-junction solar cell structures and to provide a high efficiency coating or film over the range of 300 nm to 1850 nm for space and terrestrial CPV solar cells and/or solar cell arrays.

### SUMMARY

Therefore, one embodiment of the present subject matter provides an article comprising a substrate and a sputter deposited film of silicon dioxide having a refractive index less than 1.45 at a wavelength of 550 nm.

Another embodiment of the present subject matter provides an article comprising a substrate and a sputter deposited film of silicon dioxide having an average refractive index of less than 1.41 over the wavelength range from 300 nm to 1850 nm.

A further embodiment of the present subject matter provides an article comprising a substrate and a multi-layer antireflective coating having an average front surface reflectance of less than twenty percent over the wavelength range from 300 nm to 1850 nm.

An additional embodiment of the present subject matter may provide a thin film interference filter comprising alternating layers of high refractive index material and low refractive index material wherein the low refractive index material comprises sputter deposited silicon dioxide having a refractive index less than 1.45.

One embodiment of the present subject matter may provide a photovoltaic solar cell having an antireflective coating on an outer surface wherein the antireflective coating comprises a material having a refractive index less than 1.45 at a wavelength of 550 nm.

Yet another embodiment of the present subject matter may provide a photovoltaic solar cell having an antireflective coating on an outer surface wherein the antireflective coating has an average front surface reflectance of less than twenty percent over the wavelength range from 300 nm to 1850 nm.

One embodiment may provide a photovoltaic solar cell having a multi-layer antireflective coating on an outer surface wherein the coating comprises alternating layers of silicon dioxide and tantalum pentoxide, the silicon dioxide having a refractive index less than 1.4 at a wavelength of 550 nm.

Another embodiment of the present subject matter may provide a photovoltaic solar cell having a multi-layer antireflective coating on an outer surface wherein the coating comprises alternating layers of silicon dioxide and tantalum pentoxide, the antireflective coating having an average front surface reflectance of less than five percent over the wavelength range from 300 nm to 1850 nm.

A further embodiment may provide a method of forming a film of silicon dioxide comprising the step of sputter depositing the film on a substrate at an operating pressure of at least 10 mTorr.

An additional embodiment of the present subject matter provides a method of depositing a film of silicon dioxide on a substrate. The method may comprise providing a vacuum chamber, positioning a target of silicon within the vacuum chamber, and applying power to the target to thereby effect sputtering of silicon from the target. A microwave generator may be positioned within the vacuum chamber and oxygen introduced into the vacuum chamber proximate to the microwave generator. Power may be applied to the microwave generator to thereby generate a plasma containing monatomic oxygen. The substrate may be moved past the target to effect the deposition of silicon on the substrate and then moved past the microwave generator to effect the reaction of silicon with oxygen to thereby form silicon dioxide on the substrate. Pressure within the chamber may be maintained at a pressure of at least 10 mTorr during the sputtering and reaction of silicon to thereby form a film of silicon dioxide on the substrate.

These embodiments and many other objects and advantages thereof will be readily apparent to one skilled in the art to which the invention pertains from a perusal of the claims, the appended drawings, and the following detailed description of the embodiments.

### BRIEF DESCRIPTION OF THE DRAWINGS

FIG. 1 is a simplified diagram of a multi junction solar cell according to an embodiment of the present subject matter.

FIG. 2 is a graphical representation of reflectance verses wavelength for an embodiment of the present subject matter.

FIG. 3 is a graphical representation of the ASTM G173-03 solar spectra.

FIG. 4 is a graphical representation of the reflectance of a typical multi-junction solar cell with and without an applied antireflective coating according to an embodiment of the present subject matter.

FIG. 5 is a perspective view of a magnetron sputtering system.

FIG. 6 is a perspective view of a sputtering system having tooling allowing more than one degree of rotational freedom.

FIG. 7 is a graphical representation of index of refraction comparison between a standard silicon dioxide layer and a silicon dioxide layer according to an embodiment of the present subject matter.

### DETAILED DESCRIPTION OF THE DRAWINGS

With reference to the figures where like elements have been given like numerical designations to facilitate an understanding of the present subject matter, the various embodiments of an antireflection coating for multi-junction solar cells and methods are herein described.

Thin films and thin-film technology have played an important role in photovoltaic (PV) and concentrated photovoltaic (CPV) power generation for terrestrial and space-qualified applications. Traditionally, the top layer of solar cells has been a thin cover glass, coated with a conventional anti-reflection (AR) coating. This cover glass may also serve as a radiation barrier, as an optical-coupling element, and/or as a protective agent against debris, impact and other environmental aggressors. Thus, exemplary thin-film coatings are generally considered important to the performance and environmental robustness of PV systems.

Exemplary functional PV materials may thus be engineered to maximize the conversion of every photon in the solar spectrum into charge carriers. Materials ranging from crystalline silicon (c-Si) to thin-film-based amorphous silicon (α-Si) and from copper indium gallium diselenide (CIGS) to III-V compounds are commonly employed. Exemplary solar cell designs according to embodiments of the present subject matter may range from single-junction to multi junction or inverted multi-junction, and from monolithic to multi-element construction. Exemplary systems may be terrestrial-based systems (e.g., AM 1.5, etc.) or space-based systems (AM 0). Further exemplary terrestrial-based systems according to embodiments of the present subject matter may include one-sun systems and concentrator systems (5-1000 suns) which employ lenses and/or mirrors as a primary light collector.

As the technology for solar cell construction has evolved, so has the need for these thin-film coatings, both simple and complex, employed on solar system elements such as, but not limited to, lenses, collectors, mirrors and the solar cell itself. AR coatings according to embodiments of the present subject matter may be applied to lenses of exemplary terrestrial- and/or spaced-based systems and also may be applied as a top layer on the cell to increase the photon flux reaching the PV medium, while reflecting part of the incident energy that nets only unwanted cell heating. For example, in an exemplary multi junction solar cell, one AR coating may further tailor the spectral response in order to match the currents at the different junctions. Thus, the AR coating may be employed as a multi-purpose spectral/current regulation coating.

Multilayer coatings according to embodiments of the present subject matter may also be utilized in exemplary solar cells. It its basic form, a solar cell is a semiconductor device designed to generate electric power when exposed to electromagnetic radiation. Distribution of light in outer space generally resembles theoretical radiation provided by a black body; however, as the light passes through the atmosphere, some of the light may be absorbed or reflected by gasses such as water vapor, carbon dioxide, ozone, etc. Thus, the typical distribution of light on the surface of the earth is different than the distribution of light in space, and engineers should consider the spectrum of incident light on a solar cell employing coatings according to embodiments of the present subject matter as a function of the environment in which the solar cell is utilized. A solar cell according to one embodiment of the present subject matter may comprise one or more p-n junctions whereby light enters the semiconductor material through the n region and generates an electron-hole pair (“EHP”) in the material due to the photoelectric effect. The n region may be substantially thin while the depletion region thick. If the EHP is generated in the depletion region, the built-in electric field drifts the electron and hole apart resulting in a current though the device called a photocurrent. If the EHP is generated in the n or p regions, the electron and hole may drift in random directions and may or may not become part of the photocurrent. Performance of a solar cell may be measured by several terms: short-circuit current (current of a solar cell when the negative and positive leads (top and bottom of cell) are connected with a short circuit); open-circuit voltage (voltage between top and bottom of a solar cell); power point (point on the current-voltage curve of a solar cell that generates the maximum amount of power for the device); fill factor (a value that describes how close the current-voltage curve of a solar cell resembles an ideal solar cell); quantum efficiency (number of EHPs that are created and collected divided by the number of incident photons); external quantum efficiency (EQE) (a function of the flux of photons reaching the photovoltaic medium); overall efficiency (percent of incident electromagnetic radiation that is converted to electrical power).

With single layer solar cells, much of the energy of incident light is not converted into electricity. If an incident photon has less energy than the bandgap of the semiconductor material (i.e., the energy difference or range (in eV) between the top of the valence band and the bottom of the conduction band and is the amount of energy required to free an outer shell electron to a free state), the photon cannot be absorbed since there is not enough energy to excite an electron from the conduction band to the valence band; therefore, none of the light with less energy than the bandgap is used in the solar cell. If an incident photon has more energy than the bandgap, the excess energy will be converted into heat since the electron can only absorb the exact amount of energy required to move to the valence band. Multi junction solar cells make better use of the solar spectrum by having multiple semiconductor layers with different bandgaps. Each layer may be made of a different material (usually a III-V semiconductor but may also be a II-VI semiconductor) and may absorb a different portion of the spectrum. Generally, the top layer provides the largest bandgap so that the most energetic photons are absorbed in this layer. Less energetic photons must pass through the top layer since they are not energetic enough to generate EHPs in the material. Each layer going from the top to the bottom may have a smaller bandgap than the previous layer; therefore, each layer may absorb photons having energies greater than the bandgap of that layer and less than the bandgap of a higher layer. One exemplary form of a multi junction solar cell may comprise three layers and may be generally termed as a triple-junction solar cell. Of course, such an example should not limit the scope of the claims appended herewith as coatings and films according to embodiments of the present subject matter may be employed in any number of types of solar cells.

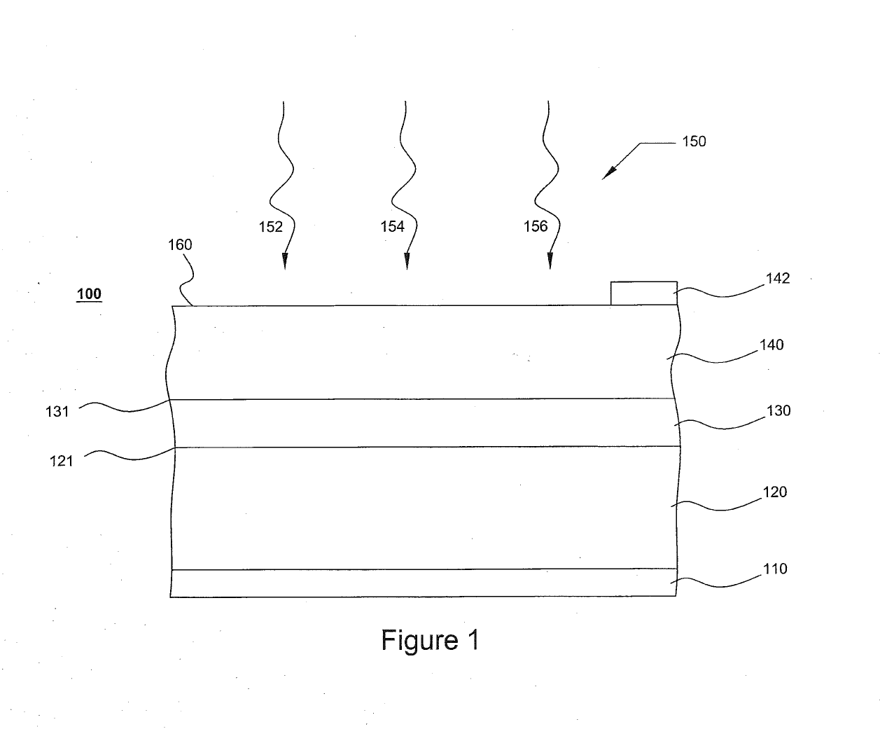

FIG. 1 is a simplified diagram of a multi-junction solar cell according to an embodiment of the present subject matter. With reference to FIG. 1, a multi-junction solar cell 100 may comprise multiple cells where each cell is responsible for converting a different portion of the solar spectrum. The embodiment shown in FIG. 1 is a triple-junction solar cell comprising a bottom cell 120, a middle cell 130, and an upper cell 140. Of course, this triple-junction solar cell is exemplary only and should not limit the scope of the claims appended herewith as many more or less junctions may be utilized in embodiments of the present subject matter to increase the performance of the solar cell. The solar cell 100 may also include two contacts 110 and 142 such as, but not limited to, metal conductive pads employed to transport electrical current in the multi junction solar cell 100. Any leads (not shown) to or from the contacts 110, 142 may link the multi-junction solar cell 100 to other neighboring solar cell structures and/or other electrical devices. Thus, it should be appreciated to one skilled in the art that it does not depart from the scope of the present subject matter by adding additional blocks, circuits, and/or elements to the multi-junction solar cell structure 100.

Any of the cells 120, 130, 140 may be homo-junction or hetero junction cells; however, hetero junction cells generally provide a higher bandgap than homo-junction cells by enhancing light passivation to adjacent and lower cells. Another advantage associated with high bandgap hetero junction cells may be to provide better lattice-matching to thereby increase solar spectrum coverage. For example, a high bandgap hetero-junction middle cell 130 may absorb a larger portion of the solar spectrum than a homo-junction middle cell. Further, a high bandgap hetero-junction middle cell may also provide a higher open circuit voltage and higher short circuit current, that is, sunlight generated photocurrent may increase with a higher bandgap emitter hetero junction.

Sunlight 150 incident on the solar cell 100 may include a plurality of groups of photons including photons 152 from a high frequency portion of the solar spectrum, photons 154 from at least the visible light portion of the solar spectrum, and photons 156 from the low frequency portion of the solar spectrum. The top cell 140, which may include a homo-junction or hetero-junction, may absorb photons 152 and allow photons 154, 156 to pass through the top solar cell 140. Upon absorption of the photons 152, the top cell 140 converts these photons to electrical energy and passes the electrical energy together with the electrical energy generated from the middle and bottom cells 130, 120 to the contact 142 which, in turn, may pass the electrical energy to the next stage, e.g., neighboring solar cells and/or electrical devices.

The middle cell 130, which may include a homo-junction or hetero-junction, may absorb photons 154 and allow other photons 156 to reach the bottom cell 120. The middle cell 130 may convert the photons 154 to electrical energy and subsequently pass the electrical energy together with the electrical energy generated from the bottom cell 120 to the top cell 140. The bottom cell 120, which may include a homo-junction or hetero-junction, may absorb photons 156, subsequently convert these photons to electrical energy, and pass the electrical energy to the middle cell 130. In one embodiment, the bottom cell 120 may include a germanium (Ge) based substrate or a gallium arsenide (GaAs) based substrate. The cells 120, 130, 140 may be formed from any or combination of III-V or II-VI semiconductor materials. For example, the middle cell 130 may include an indium gallium phosphide (InGaP) layer for an emitter and an indium gallium arsenide (InGaAs) layer for base. Generally, InGaAs has a close lattice match to a Ge-based substrate. It should be noted that the cells may be formed by any combination of groups III, IV, V and VI elements in the periodic table; for example, the group III may include boron (B), aluminum (Al), gallium (Ga), indium (In), and thallium (Tl), the group IV may include carbon (C), silicon (Si), Ge, and tin (Sn), the group V may include nitrogen (N), phosphorus (P), arsenic (As), antimony (Sb), and bismuth (Bi), and so forth; thus the previous example for the middle cell 130 should not limit the scope of the claims appended herewith as a multitude of materials may be employed in any of the cells. For example, the top cell 140 may comprise primarily GaInP, the middle cell 130 may comprise primarily GaAs, and the bottom cell 120 may comprise InGaAs. In another embodiment, the top cell 140 may comprise primarily GaInP, the middle cell 130 may comprise primarily AlInP, and the bottom cell 120 may comprise primarily a GeAs substrate. Furthermore, doping concentrations in any of the cells may be varied and adjacent cells may comprise, for example, p-GaInN, n-GaInN, n-InN, p-InN, and so forth.

The efficiency of exemplary solar cells may generally be limited by the efficiency of the least efficient junction. Typical junctions operate in the regions between 300 nm to 550 nm, 700 nm to 880 nm, and 900 nm to 1800 nm. Spectrally selective or antireflective coatings according to embodiments of the present subject matter may be employed to balance and/or enhance the solar energy thereby optimizing the efficiency of a solar cell. For example, an exemplary multilayer coating 160 may be deposited to the surface receiving incident sunlight. While not explicitly depicted, the coating 160 may include a multitude of layers, thus, the simplistic diagram of FIG. 1 should not so limit the claims appended herewith. For example, the coating 160 may include, in one embodiment, fourteen layers comprised of alternating materials having a high refractive index and materials having a low refractive index. Of course, the coating 160 may include any number of layers, whether odd or even, and the previous example is not intended to limit the scope of claims appended herewith. This coating 160 may be utilized to modulate the luminous flux (i.e., anti-reflection) across the operating band of each junction and match the luminous flux to quantum efficiency of the junction in most need of photons. Another embodiment of the present subject matter may apply one or more multilayer coatings at the interfaces 121, 131 of any one or several of the cells 120, 130, 140 to provide active control of the luminous flux delivered to each junction by becoming more/less transmissive when current is applied thereto. Thus, these exemplary coatings may employ an electro-chromic effect to modulate photon throughput to each junction and thereby the quantum efficiency for the entire solar cell 100.

Therefore, one embodiment of the present subject matter may be a thin-film interference filter applied to a surface of any multi-junction solar cell such as that depicted in FIG. 1. For example, an embodiment of the present subject matter may provide a thin film interference filter comprising alternating layers of high refractive index material and low refractive index material where the low refractive index material comprises sputter deposited silicon dioxide having a refractive index less than 1.45. In additional embodiments, the low refractive index material may have a refractive index of less than 1.4, less than 1.38 or approximately 1.3. This exemplary film may thus behave as a coupler of the solar radiant flux into the semiconductor material and act as an anti-reflection coating. The minimization of the integrated reflectance, and thus the maximization of the anti-reflection property, between the incident medium and the top-most junction in a multi-junction solar cell may in certain embodiments maximize the conversion of the number of photons into a photo-current in the semiconductor material. One exemplary AR coating may function between 300-2500 nm, and minimize the response provided in equation (1) below.

∫_{300 nm}^{2500 nm}R(λ)θλ (1)

The application of a multi-layer reactively sputtered film according to one embodiment of the present subject matter to a multi junction solar cell may thus provide a broad antireflection band in exemplary solar cells, solar arrays, etc. As the selection of materials for optical properties and environmental robustness is important in the CPV industry, coatings employing one or several of titanium dioxide, niobium pentoxide, tantalum pentoxide, hafnium dioxide, and silicon dioxide may provide large optical, thermal and mechanical advantages in the construction of broad-band, angle insensitive, and durable AR coatings.

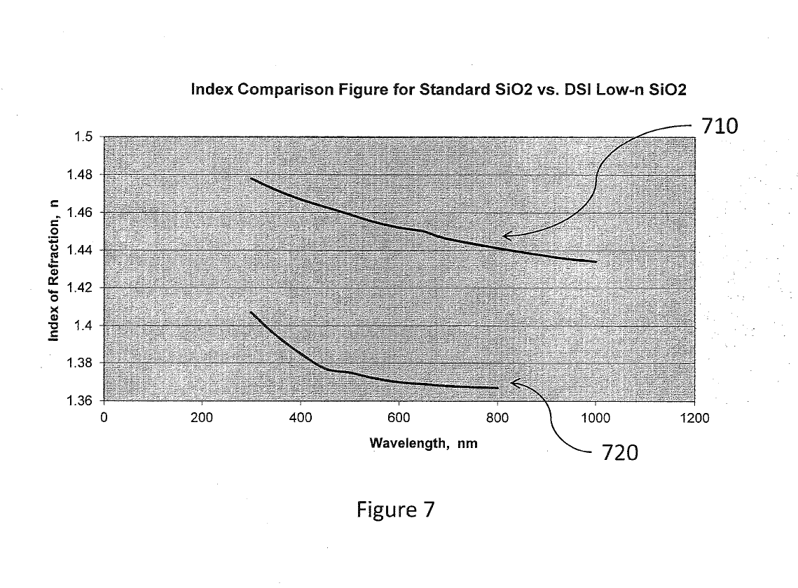

One exemplary coating according to an embodiment of the present subject matter may be reactively sputtered into a porous film. Exemplary methods according to embodiments of the present subject matter may increase or decrease the deposition pressure during the sputtering process thereby providing a resultant film growth orientation that lowers the index of refraction of the sputtered material from 1.45 to as much as 1.1. FIG. 7 is a graphical representation of index of refraction comparison between a standard silicon dioxide layer 710 and a silicon dioxide layer according to one embodiment of the present subject matter 720. Table 1A provides the indices of refraction for Standard SiO₂ coating 710. Table 1B provides the indices of refraction for low-n SiO₂ coating 720.

TABLE 1A

| | Standard SiO₂ coating |
|---|---|
| | index of refraction (n) |
| Wavelength (nm) | (710) |
| 300 | 1.478 |
| 350 | 1.472 |
| 400 | 1.467 |
| 450 | 1.463 |
| 500 | 1.459 |
| 550 | 1.455 |
| 600 | 1.452 |
| 650 | 1.45 |
| 700 | 1.446 |
| 900 | 1.437 |
| 1000 | 1.434 |

TABLE 1B

| | Low-n SiO2 coating index |
|---|---|
| Wavelength (nm) | of refraction (n) |
| 300 | 1.407 |
| 350 | 1.395 |
| 400 | 1.385 |
| 450 | 1.377 |
| 500 | 1.375 |
| 550 | 1.372 |
| 600 | 1.37 |
| 650 | 1.369 |
| 700 | 1.368 |
| 800 | 1.367 |

With reference to FIG. 7 and Tables 1A and 1B, it is apparent that an SiO₂ coating according to an embodiment of the present subject 720 matter exhibits marked lower indices of refraction in the spectral band of 300 nm to 800 nm as compared to a standard SiO₂ coating. Most notably are the low indices of refraction exhibited in the high energy spectral band of 300 nm to 400 nm. Therefore, the utilization of a low index metal oxide, e.g., titanium dioxide, niobium pentoxide, hafnium dioxide, tantalum pentoxide, and silicon dioxide film in the AR filter or coating for a multi junction solar cell may thus enable a higher capture ratio of high energy (e.g., blue) photons in the 300 nm to 400 nm spectral band. One advantage of having more of these photons available is the ability to correct for current limiting effects in the solar cell morphology.

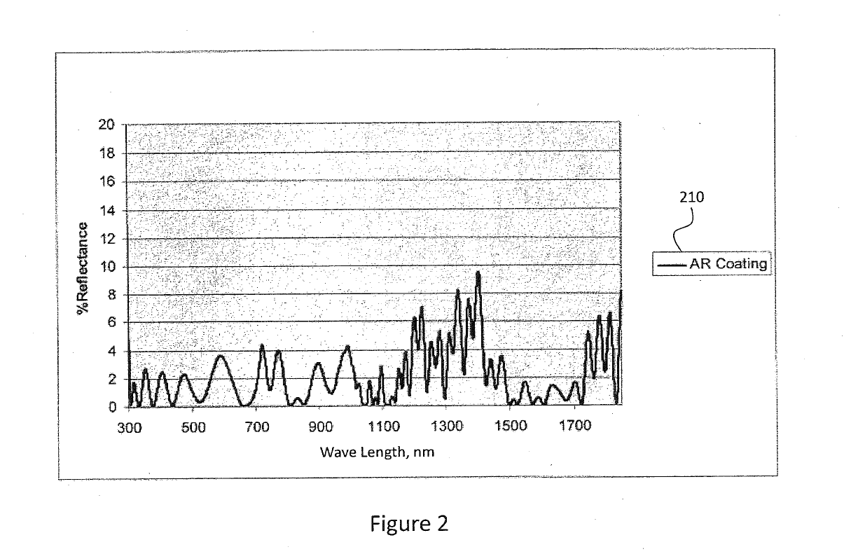

Another embodiment of the present subject matter may provide a reduction of reflectance (R) on a solar cell to less than 2.25% from 300 nm to wavelengths greater than 800 nm as shown in the experimentally achieved spectrum exhibited in FIG. 2. FIG. 2 is a graphical representation of reflectance (R) verses wavelength in nm for a broadband antireflective (BBAR) coating 210 according to an embodiment of the present subject matter. Another embodiment may provide a reduction of R on any solar cell to less than 2.25% between 300 and 1850 nm as shown in the experimentally achieved spectrum exhibit in FIG. 2. An exemplary material for the BBAR coating may be silicon dioxide, however, other coatings may be employed such as, but not limited to, titanium dioxide, tantalum pentoxide, niobium pentoxide, hafnium dioxide, etc. Such coatings may also be porous to thereby affect the AR properties thereof as appropriate.

One embodiment of the present subject matter may thus provide an article or device having a substrate and a sputter deposited film of silicon dioxide having a refractive index less than 1.45 at a wavelength of 550 nm. Other embodiments may include a silicon dioxide film with lower indices of refraction from 1.4 to as low as approximately 1.3 at the wavelength of 550 nm.

As previously mentioned, the efficiency of a photovoltaic (PV) solar cell may be quantified by a number of metrics, one being the external quantum efficiency (EQE) of the device. Whether a PV solar cell is single-junction or multi-junction, its EQE is a function of the flux of photons reaching the PV medium. It is, therefore, important to optically match the PV solar cell to the incident medium (air/space) in which it operates thereby requiring the addition of one or more interfaces between the solar cell and the incident medium in the form of an AR coating according to an embodiment of the present subject matter. One embodiment of the present subject matter may thus provide a photovoltaic solar cell having an AR coating on an outer surface wherein the antireflective coating comprises a material having a refractive index less than 1.45 at a wavelength of 550 nm. This material may be silicon dioxide and may also be sputter deposited. In yet another embodiment, the AR coating may include alternating layers of the silicon dioxide and a second material such as, but not limited to, titanium dioxide, hafnium dioxide, tantalum pentoxide, and niobium pentoxide.

A further embodiment of the present subject matter may provide a photovoltaic solar cell having an AR coating on an outer surface wherein the antireflective coating has an average front surface reflectance of less than twenty percent over the wavelength range from 300 nm to 1850 nm. In other embodiments, the AR coating may have an average front surface reflectance of less than fifteen percent, less than ten percent, less than five percent, and even less than three percent over the wavelength range from 300 nm to 1850 nm. The AR coating may include alternating layers of high refractive index material and low refractive index material where the low refractive index material includes sputter deposited silicon dioxide having a refractive index less than 1.4 at a wavelength of 550 nm. Of course, the low refractive index material may have an index less than 1.38 at a wavelength of 550 nm in an additional embodiment.

One embodiment may provide a photovoltaic solar cell having a multi-layer antireflective coating on an outer surface wherein the coating comprises alternating layers of silicon dioxide and tantalum pentoxide, the silicon dioxide having a refractive index less than 1.4 at a wavelength of 550 nm. The outermost layer of the multi-layer AR coating may include silicon dioxide, and in another embodiment, the innermost layer of the multi-layer AR coating may include tantalum pentoxide.

Another embodiment of the present subject matter may provide a photovoltaic solar cell having a multi-layer antireflective coating on an outer surface wherein the coating comprises alternating layers of silicon dioxide and tantalum pentoxide, the antireflective coating having an average front surface reflectance of less than five percent over the wavelength range from 300 nm to 1850 nm. In one embodiment, the silicon dioxide may have a refractive index less than 1.4 at a wavelength of 550 nm.

The design of an AR coating may be characterized by the irradiance, emittance and absorptance of the sources and media in which the AR coating operates and may also be characterized by the optical properties, index of refraction and extinction coefficient of the coating materials and substrates used in the attendant optical system. The spectral band over which the coating operates defines the anti-reflection problem. For example, in PV solar cells this implies the solar spectra.

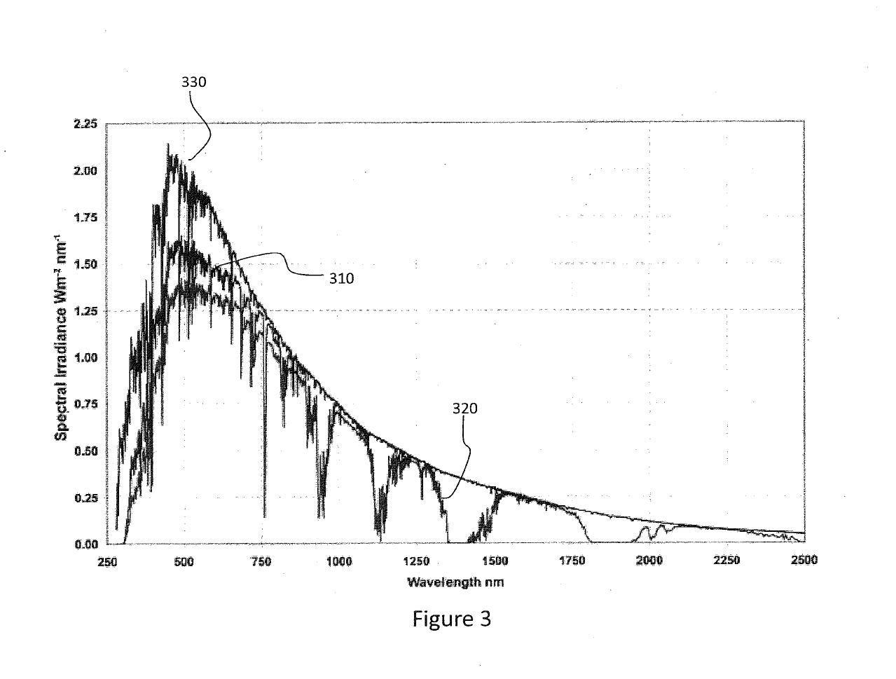

FIG. 3 is a graphical representation of the ASTM G173-03 solar spectra. With reference to FIG. 3, the inputs to an exemplary PV device are the solar spectra, represented by the ASTM G173-03 standard with terrestrial solar spectral irradiance on a specifically oriented surface under a set of atmospheric conditions. A first curve 310 provides a global tilted irradiance spectrum in W*m²/nm. A second curve 320 provides a direct and circumsolar irradiance spectrum in W*m²/nm. A third curve 330 provides an extraterrestrial irradiance spectrum in W*m²/nm. These three curves establish an envelope for an integrated photon input to the PV medium in the functional 300-2500 nm band. As shown in FIG. 3, approximately five percent of the solar spectrum falls in the 1900-2500 nm range; however, this spectral region is normally non-operative as it consists primarily of unwanted heat. Generally, an optimized broadband solar AR coating should operate in the 300-1850 nm band.

Thus, the design of an exemplary BBAR coating for a solar cell system should take into consideration the optical properties of the PV materials and the complementary optical thin films. The front surface Fresnel reflectance for an interface may be calculated following the relationship:

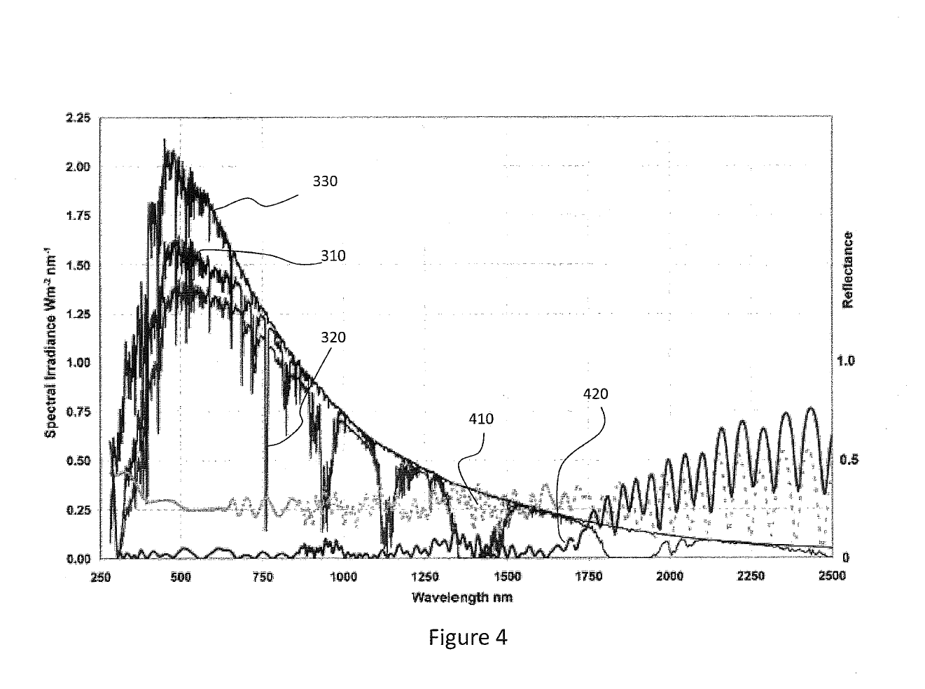

R=[(nₘₐₜₑᵣᵢₐₗ−n_{medium})²+kₘₐₜₑᵣᵢₐₗ²]/[(nₘₐₜₑᵣᵢₐₗ+n_{medium})²+kₘₐₜₑᵣᵢₐₗ²] (2)

where nₘₐₜₑᵣᵢₐₗ represents the index of refraction a material, n_{medium} represents the index of refraction of a medium and kₘₐₜₑᵣᵢₐₗ represents the extinction coefficient of the material. For example, for the majority of the III-V elements and compounds, nₘₐₜₑᵣᵢₐₗ generally falls within the 3.0 to 5.0 range thus resulting in front-surface reflectance losses (in AM 1.5) somewhere between Rₘₐₓ˜25 to 45%. Thus, by employing a robust multi-level BBAR coating matched to the AM 1.5 solar spectrum, the front surface reflectance may be reduced to R_{avg}≦3% over the 300 nm-1800 nm operating band. FIG. 4 is a graphical representation of the reflectance of a typical multi junction solar cell with and without an applied AR coating according to an embodiment of the present subject matter. FIG. 4 provides the global tilted, direct and circumsolar, and extraterrestrial irradiance spectra 310, 320, 330 of FIG. 3 and also provides a curve showing a multi-junction solar cell without an exemplary AR coating 410 and provides a curve showing a multi-junction solar cell with an exemplary AR coating 420 according to one embodiment of the present subject matter. With reference to FIG. 4, it is apparent to one of ordinary skill that the application of a multi-layer BBAR according to an embodiment of the present subject matter may result in a 3 to 5% gain in the EQE for multi-junction solar cells (under 500× concentration) when compared to the EQE of the same cell using a conventional V-coat AR. This performance gain in solar cell efficiency makes it possible for commercially available solar cells to achieve a 40 to 50% conversion efficiency range.

The design of an AR coating may be characterized by the irradiance, emittance and absorptance of the sources and media in which the AR coating operates and may also be characterized by the optical properties, index of refraction and extinction coefficient of the coating materials and substrates used in the attendant optical system. The spectral band over which the coating operates defines the anti-reflection problem. For example, in PV solar cells this implies the solar spectra.

Thus, one embodiment of the present subject matter may provide an article or device including a substrate and a sputter deposited film of silicon dioxide having an average refractive index of less than 1.41 over the wavelength range from 300 nm to 1850 nm. This sputter deposited film of silicon dioxide may also a refractive index less than 1.4 at a wavelength of 550 nm in another embodiment.

A further embodiment of the present subject matter may provide an article or device having a substrate and a multi-layer antireflective coating with an average front surface reflectance of less than twenty percent over the wavelength range from 300 nm to 1850 nm. In other embodiments, the multi-layer AR coating may have an average front surface reflectance of less than fifteen percent, less than ten percent, less than five percent, and even less than three percent over the wavelength range from 300 nm to 1850 nm. Of course, the multi-layer AR coating may include alternating layers of high refractive index material and low refractive index material where the low refractive index material is sputter deposited silicon dioxide having a refractive index less than 1.4 at a wavelength of 550 nm. In additional embodiments the layer of low refractive index material may have a refractive index of less than 1.38 at the wavelength of 550 nm. Of course, this multi-layer AR coating may possess an average front surface reflectance of less than five percent and even less than three percent over the wavelength range from 300 nm to 1850 nm. In one exemplary embodiment, the high refractive index material may include one or more materials selected from the group of titanium dioxide, hafnium dioxide, tantalum pentoxide, and niobium pentoxide.

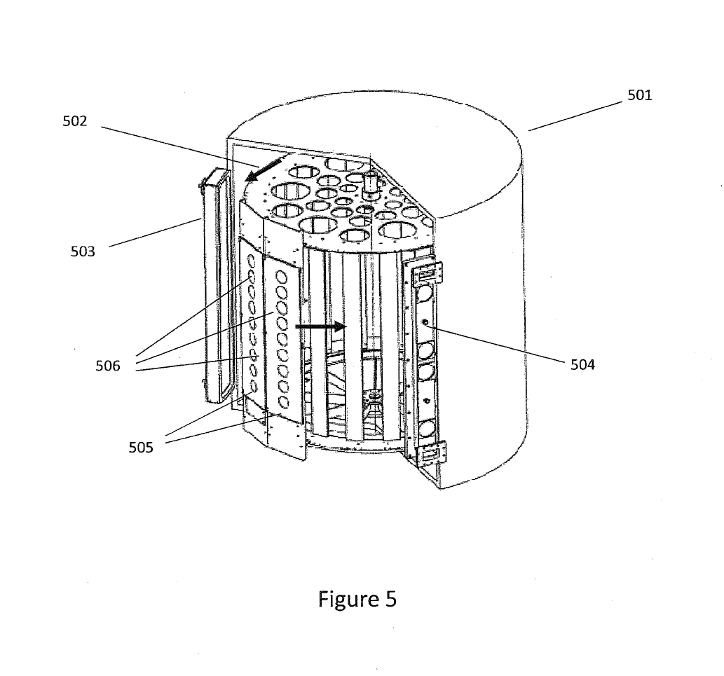

Multilayer coatings according to embodiments of the present subject matter may be manufactured or produced by any number of methods. For example, exemplary coatings may be sputtered utilizing a magnetron sputtering system. FIG. 5 is a perspective view of an exemplary magnetron sputtering system. With reference to FIG. 5, the magnetron sputtering system may utilize a cylindrical, rotatable drum 502 mounted in a vacuum chamber 501 having sputtering targets 503 located in a wall of the vacuum chamber 501. Plasma or microwave generators 504 known in the art may also be located in a wall of the vacuum chamber 501. Substrates 506 may be removably affixed to panels or substrate holders 505 on the drum 502.

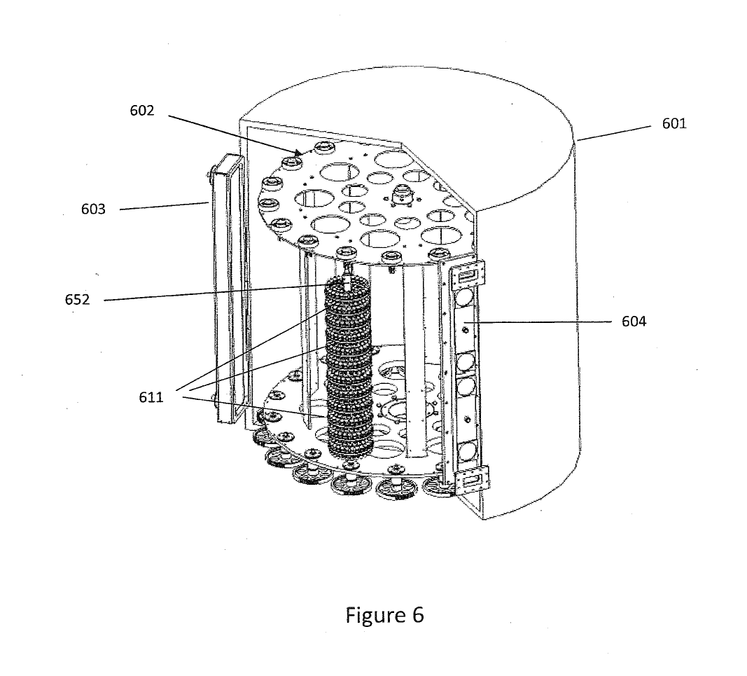

Embodiments of the present subject matter may also be manufactured in sputtering systems having tooling allowing more than one degree of rotational freedom. FIG. 6 is a perspective view of a such a sputtering system. With reference to FIG. 6, an exemplary sputtering system may utilize a substantially cylindrical, rotatable drum or carrier 602 mounted in a vacuum chamber 601 having sputtering targets 603 located in a wall of the vacuum chamber 601. Plasma or microwave generators 604 known in the art may also be located in a wall of the vacuum chamber 601. The carrier 602 may have a generally circular cross-section and is adaptable to rotate about a central axis. A driving mechanism (not shown) may be provided for rotating the carrier 602 about its central axis. A plurality of pallets 650 may be mounted on the carrier 602 in the vacuum chamber 670. Each pallet 650 may comprise a rotatable central shaft 652 and one or more disks 611 axially aligned along the central shaft 652. The disks 611 may provide a plurality of spindle carrying wells positioned about the periphery of the disk 611. Spindles may be carried in the wells, and each spindle may carry one or more substrates adaptable to rotate about it respective axis. Additional particulars and embodiments of this exemplary system are further described in co-pending and related U.S. patent application Ser. No. 12/155,544, filed Jun. 5, 2008, entitled, “Method and Apparatus for Low Cost High Rate Deposition Tooling,” and co-pending U.S. application Ser. No. 12/289,398, filed Oct. 27, 2008, entitled, “Thin Film Coating System and Method,” the entirety of each being incorporated herein by reference. Of course, embodiments of the present subject matter may also be manufactured using an in line coating mechanism or sputtering system and/or any conventional chemical vapor deposition system. Further, to obtain sufficient uniformity in coating may require plural rotations past the target or may require multiple targets.

In the aforementioned processing methods and systems, a film of silicon dioxide according to one embodiment of the present subject matter may be sputter deposited onto a substrate at an operating pressure of at least 10 mTorr and preferably between 10 mTorr and 25 mTorr. For example, in one embodiment using a magnetron sputtering system similar to that depicted in FIG. 5, operating pressure was maintained at 22 mTorr, argon flow at 305 sccm, target power at 5.0 kW, O₂ partial pressure at 0.45 mTorr, and a drum rotation of 60 rpm. With these values, a rate of deposition of 18 nm per minute was achieved thereby resulting in an index of refraction of a metal oxide film of approximately 1.372 at a wavelength of 550 nm. The metal oxide film may, of course, be silicon dioxide film and possess a refractive index of between 1.45 and 1.3 at a wavelength of 550 nm depending upon the process conditions utilized.

One embodiment of the present subject matter may include a method of depositing a film of silicon dioxide on a substrate. This may be accomplished utilizing the magnetron systems depicted in FIGS. 5 and 6, inline systems or other conventional sputtering systems. The method may include providing a vacuum chamber having one or more microwave generators therein and positioning a target of silicon or another substrate within the vacuum chamber. Power may then be applied to the target to thereby effect sputtering of silicon from the target. Oxygen may be introduced into the vacuum chamber proximate to the microwave generator and power applied to the microwave generator thereby generating a plasma containing monatomic oxygen. The substrate may be moved past the target to effect the deposition of silicon on the substrate and then moved past the microwave generator to effect the reaction of silicon with oxygen to form silicon dioxide on the substrate. Of course, additional layers of materials may be sputter deposited upon the substrate or surface thereof. The pressure within the chamber may be maintained at a pressure of at least 10 mTorr and preferably between 10 mTorr and 25 mTorr during the sputtering and reaction of silicon to thereby form a film of silicon dioxide on the substrate. In one embodiment, the silicon dioxide film may possess a refractive index of between 1.45 and 1.3 at a wavelength of 550 nm depending upon the process conditions utilized.

It is thus an aspect of embodiments of the present subject matter to provide higher collection and conversion efficiencies for commercial CPV systems whereby an exemplary thin-film optical coating provides an important role in the performance of both collection optics and cell-level performance. It is also an aspect of embodiments of the present subject matter to provide an environmentally stable, ultra-durable BBAR coating for multi junction metamorphic and lattice-matched solar cells. Such coatings may demonstrate as much as a five percent relative gain in the conversion efficiency of solar cell devices.

As shown by the various configurations and embodiments illustrated in FIGS. 1-7, the various embodiments of an antireflection coating for multi-junction solar cells and methods have been described.

While preferred embodiments of the present subject matter have been described, it is to be understood that the embodiments described are illustrative only and that the scope of the invention is to be defined solely by the appended claims when accorded a full range of equivalence, many variations and modifications naturally occurring to those of skill in the art from a perusal hereof.

What we claim is:

1. An article comprising a substrate and a sputter deposited film of silicon dioxide having a refractive index less than 1.45 at a wavelength of 550 nm.

2. The article of claim 1 wherein the refractive index of said sputter deposited film of silicon dioxide is less than 1.4 at a wavelength of 550 nm.

3. The article of claim 2 wherein the refractive index of said sputter deposited film of silicon dioxide is less than 1.38 at a wavelength of 550 nm.

4. The article of claim 3 wherein the refractive index of said sputter deposited film of silicon dioxide is about 1.3 at a wavelength of 550 nm.

5. An article comprising a substrate and a sputter deposited film of silicon dioxide having an average refractive index of less than 1.41 over the wavelength range from 300 nm to 1850 nm.

6. The article of claim 5 wherein said sputter deposited film of silicon dioxide has a refractive index less than 1.4 at a wavelength of 550 nm.

7. An article comprising a substrate and a multi-layer antireflective coating having an average front surface reflectance of less than twenty percent over the wavelength range from 300 nm to 1850 nm.

8. The article of claim 7 wherein said multi-layer antireflective coating has an average front surface reflectance of less than fifteen percent over the wavelength range from 300 nm to 1850 nm.

9. The article of claim 8 wherein said multi-layer antireflective coating has an average front surface reflectance of less than ten percent over the wavelength range from 300 nm to 1850 nm.

10. The article of claim 9 wherein said multi-layer antireflective coating has an average front surface reflectance of less than five percent over the wavelength range from 300 nm to 1850 nm.

11. The article of claim 10 wherein said multi-layer antireflective coating has an average front surface reflectance of less than three percent over the wavelength range from 300 nm to 1850 nm.

12. The article of claim 7 wherein said multi-layer antireflective coating comprises alternating layers of high refractive index material and low refractive index material wherein said low refractive index material comprises sputter deposited silicon dioxide having a refractive index less than 1.4 at a wavelength of 550 nm.

13. The article of claim 12 wherein said multi-layer antireflective coating comprises alternating layers of high refractive index material and low refractive index material wherein said low refractive index material comprises sputter deposited silicon dioxide having a refractive index less than 1.38 at a wavelength of 550 nm.

14. The article of claim 12 wherein said multi-layer antireflective coating has an average front surface reflectance of less than five percent over the wavelength range from 300 nm to 1850 nm.

15. The article of claim 14 wherein said multi-layer antireflective coating has an average front surface reflectance of less than three percent over the wavelength range from 300 nm to 1850 nm.

16. The article of claim 12 wherein said high refractive index material comprises one or more materials selected from the group consisting of titanium dioxide, hafnium dioxide, tantalum pentoxide, and niobium pentoxide.

17. A thin film interference filter comprising alternating layers of high refractive index material and low refractive index material wherein said low refractive index material comprises sputter deposited silicon dioxide having a refractive index less than 1.45.

18. The thin film interference filter of claim 17 wherein the refractive index of said silicon dioxide is less than 1.4.

19. The thin film interference filter of claim 18 wherein the refractive index of said silicon dioxide is less than 1.38.

20. The thin film interference filter of claim 19 wherein the refractive index of said silicon dioxide is about 1.3.

21. A photovoltaic solar cell having an antireflective coating on an outer surface wherein said antireflective coating comprises a material having a refractive index less than 1.45 at a wavelength of 550 nm.

22. The photovoltaic solar cell of claim 21 wherein said material comprises silicon dioxide.

23. The photovoltaic solar cell of claim 22 wherein said silicon dioxide is sputter deposited.

24. The photovoltaic solar cell of claim 22 wherein said antireflective coating comprises alternating layers of said silicon dioxide and a second material selected from the group consisting of titanium dioxide, hafnium dioxide, tantalum pentoxide, and niobium pentoxide.

25. A photovoltaic solar cell having an antireflective coating on an outer surface wherein said antireflective coating has an average front surface reflectance of less than twenty percent over the wavelength range from 300 nm to 1850 nm.

26. The photovoltaic solar cell of claim 25 wherein said antireflective coating has an average front surface reflectance of less than fifteen percent over the wavelength range from 300 nm to 1850 nm.

27. The photovoltaic solar cell of claim 26 wherein said antireflective coating has an average front surface reflectance of less than ten percent over the wavelength range from 300 nm to 1850 nm.

28. The photovoltaic solar cell of claim 27 wherein said antireflective coating has an average front surface reflectance of less than five percent over the wavelength range from 300 nm to 1850 nm.

29. The photovoltaic solar cell of claim 28 wherein said antireflective coating has an average front surface reflectance of less than three percent over the wavelength range from 300 nm to 1850 nm.

30. The photovoltaic solar cell of claim 25 wherein said antireflective coating comprises alternating layers of high refractive index material and low refractive index material wherein said low refractive index material comprises sputter deposited silicon dioxide having a refractive index less than 1.4 at a wavelength of 550 nm.

31. The photovoltaic solar cell of claim 30 wherein said antireflective coating comprises alternating layers of high refractive index material and low refractive index material wherein said low refractive index material comprises sputter deposited silicon dioxide having a refractive index less than 1.38 at a wavelength of 550 nm.

32. A photovoltaic solar cell having a multi-layer antireflective coating on an outer surface wherein said coating comprises alternating layers of silicon dioxide and tantalum pentoxide, said silicon dioxide having a refractive index less than 1.4 at a wavelength of 550 nm.

33. The photovoltaic solar cell of claim 32 wherein the outermost layer of said multi-layer antireflective coating comprises silicon dioxide.

34. The photovoltaic solar cell of claim 32 wherein the innermost layer of said multi-layer antireflective coating comprises tantalum pentoxide.

35. A photovoltaic solar cell having a multi-layer antireflective coating on an outer surface wherein said coating comprises alternating layers of silicon dioxide and tantalum pentoxide, said antireflective coating having an average front surface reflectance of less than five percent over the wavelength range from 300 nm to 1850 nm.

36. The photovoltaic solar cell of claim 35 wherein said silicon dioxide has a refractive index less than 1.4 at a wavelength of 550 nm.

37. A method of forming a film of silicon dioxide comprising sputter depositing the film on a substrate at an operating pressure of at least 10 mTorr.

38. The method of claim 37 wherein the operating pressure is at least 15 mTorr.

39. The method of claim 38 wherein the operating pressure is at least 20 mTorr.

40. The method of claim 37 wherein the operating pressure is at least 10 mTorr but not greater than 25 mTorr.

41. The method of claim 37 wherein the refractive index of the silicon dioxide film is less than 1.45 at a wavelength of 550 nm.

42. The method of claim 41 wherein the refractive index of the silicon dioxide film is less than 1.4 at a wavelength of 550 nm.

43. The method of claim 42 wherein the refractive index of the silicon dioxide film is less than 1.38 at a wavelength of 550 nm.

44. The method of claim 43 wherein the refractive index of the silicon dioxide film is less than 1.3 at a wavelength of 550 nm.

45. A method of depositing a film of silicon dioxide on a substrate comprising:
providing a vacuum chamber;
positioning a target of silicon within the vacuum chamber;
applying power to the target to thereby effect sputtering of silicon from the target;
positioning a microwave generator within the vacuum chamber;
introducing oxygen into the vacuum chamber proximate to the microwave generator;
applying power to the microwave generator to thereby generate a plasma containing monatomic oxygen;
moving the substrate past the target to effect the deposition of silicon on the substrate;
moving the substrate past the microwave generator to effect the reaction of silicon with oxygen to thereby form silicon dioxide on the substrate;
maintaining the pressure within the chamber at a pressure of at least 10 mTorr during the sputtering and reaction of silicon to thereby form a film of silicon dioxide on the substrate.

46. The method of claim 45 wherein the pressure within the chamber is maintained within a range of at least 10 mTorr but not greater than 25 mTorr.
